(19) United States
(12) Patent Application Publication
(10) Pub. No.: US 2025/0116003 A1
(43) Pub. Date: Apr. 10, 2025

(54) HEATER

(71) Applicant: Sumitomo Electric Industries, Ltd., Osaka- shi, Osaka (JP)

(72) Inventors: Daisuke SHIMAO, Osaka-shi, Osaka (JP); Koichi KIMURA, Osaka-shi, Osaka (JP); Shigenobu SAKITA, Osaka-shi, Osaka (JP); Kohei SAKAGUCHI, Osaka-shi, Osaka (JP); Katsuhiro ITAKURA, Osaka-shi, Osaka (JP)

(73) Assignee: Sumitomo Electric Industries, Ltd., Osaka-shi, Osaka (JP)

(21) Appl. No.: 18/008,677

(22) PCT Filed: Dec. 23, 2021
(86) PCT No.: PCT/JP2021/048052

§ 371 Date: Dec. 20, 2024

(51) Int. Cl. C23C 16/46; H05B 3/28

(52) U.S. Cl. CPC C23C 16/46; H05B 3/283

(57) ABSTRACT

A heater including: a base body; a high frequency electrode and a heating element arranged inside the base body; and a support body, the base body including a first surface on which a heating target is mounted, a second surface to which a first end portion of the support body is attached, a first flow path having an gas intake provided on the first surface, a second flow path having an gas exhaust provided in a region inside the support body on the second surface, and a third flow path connecting the first flow path and the second flow path, each of the high frequency electrode, the heating element, and the third flow path being arranged in a plane parallel to the first surface, the heating element and the third flow path being arranged closer to the second surface than the high frequency electrode.

### TECHNICAL FIELD

The present disclosure relates to a heater.

### BACKGROUND ART

PTL 1 discloses a ceramic member in which an RF plate and a heater plate are connected with a space being interposed therebetween. The RF plate includes a mounting surface on which a wafer as an object to be heated is mounted. Inside the RF plate, a high frequency electrode used when performing plasma treatment on the wafer is arranged. Inside the heater plate, a heating resistor is arranged. The space is provided to suppress occurrence of a leakage current flowing between the high frequency electrode and the heating resistor.

### CITATION LIST

### Patent Literature

PTL 1: Japanese Patent Laying-Open No. 2018-182280

### SUMMARY OF INVENTION

A heater of the present disclosure includes:
a base body having a disk-shape;
a high frequency electrode arranged inside the base body;
a heating element arranged inside the base body; and
a support body having a cylindrical shape,
the base body including
   a first surface on which a heating target is mounted,
   a second surface to which a first end portion of the support body is attached, and
   a flow path connected to the first surface and the second surface,
the flow path including
   a first flow path having an gas intake provided on a side of the first surface,
   a second flow path having an gas exhaust provided in a region inside the support body on a side of the second surface, and
   a third flow path connecting the first flow path and the second flow path,
each of the high frequency electrode, the heating element, and the third flow path being arranged in a plane parallel to the first surface,
the heating element and the third flow path being arranged closer to the second surface than the high frequency electrode.

### BRIEF DESCRIPTION OF DRAWINGS

FIG. 1 is a cross sectional view schematically showing a film formation device including a heater of a first embodiment.

FIG. 2 is a cross sectional view showing mainly a base body of the heater shown in FIG. 1, in an enlarged manner.

FIG. 3 is a cross sectional view taken along III-III in FIG. 2.

FIG. 4 is a cross sectional view of a third flow path in a first variation.

FIG. 5 is a cross sectional view of the third flow path in a second variation.

FIG. 6 is a cross sectional view of the third flow path in a third variation.

FIG. 7 is a cross sectional view of the third flow path in a fourth variation.

FIG. 8 is a cross sectional view of the third flow path in a fifth variation.

FIG. 9 is a cross sectional view of the third flow path in a sixth variation.

FIG. 10 is a cross sectional view showing mainly a base body of a heater of a second embodiment, in an enlarged manner.

FIG. 11 is a cross sectional view showing mainly a base body of a heater of a third embodiment, in an enlarged manner.

FIG. 12 is a cross sectional view showing mainly a base body of a heater of a fourth embodiment, in an enlarged manner.

FIG. 13 is a cross sectional view showing mainly a base body of a heater of a fifth embodiment, in an enlarged manner.

### DETAILED DESCRIPTION

### Problem to be Solved by the Present Disclosure

It is desirable to uniformly heat a heating target over the entire surface. It is desirable to suppress unevenness in film formation on a heating target by plasma treatment. The technique described in PTL 1 has room for improvement in terms of uniformly heating a heating target and uniformly forming a film on the heating target.

One object of the present disclosure is to provide a heater that can uniformly heat a heating target over the entire surface, and can suppress unevenness in film formation on the heating target.

### Advantageous Effect of the Present Disclosure

A heater of the present disclosure can uniformly heat a heating target over the entire surface, and can suppress unevenness in film formation on the heating target.

### DESCRIPTION OF EMBODIMENTS OF THE PRESENT DISCLOSURE

First, embodiments of the present disclosure will be listed and described.
(1) A heater according to one aspect of the present disclosure includes
a base body having a disk-shape;
a high frequency electrode arranged inside the base body;
a heating element arranged inside the base body; and
a support body having a cylindrical shape,
the base body including
   a first surface on which a heating target is mounted,
   a second surface to which a first end portion of the support body is attached, and
   a flow path connected to the first surface and the second surface,
the flow path including
   a first flow path having an gas intake provided on a side of the first surface,
   a second flow path having an gas exhaust provided in a region inside the support body on a side of the second surface, and
   a third flow path connecting the first flow path and the second flow path,
each of the high frequency electrode, the heating element, and the third flow path being arranged in a plane parallel to the first surface,
the heating element and the third flow path being arranged closer to the second surface than the high frequency electrode.

In the heater of the present disclosure, the heating target mounted on the first surface is vacuum-suctioned onto the first surface by the flow path provided in the base body. By this vacuum suction, even if the heating target is a plate-like body having warpage before being mounted on the first surface, the warpage is corrected. The heating target mounted on the first surface can contact the first surface, over the entire surface. The heating element is arranged in a plane parallel to the first surface. Accordingly, in the heater of the present disclosure, the heating target mounted on the first surface is uniformly heated over the entire surface by the heating element.

In the heater of the present disclosure, the heating element and the third flow path are located closer to the second surface than the high frequency electrode. That is, the heating element and the third flow path do not exist between the high frequency electrode and the first surface. The high frequency electrode is arranged in a plane parallel to the first surface. Since the heating element and the third flow path do not exist between the high frequency electrode and the first surface, the thickness of the base body located between the heating target mounted on the first surface and the high frequency electrode is easily uniformly ensured. Since the third flow path does not exist between the high frequency electrode and the first surface, occurrence of discharge between the heating target and the high frequency electrode can be suppressed, and occurrence of energy loss can be suppressed.

Generally, a shower head that generates a reactive gas used for plasma treatment also serves as a high frequency electrode paired with the high frequency electrode described above, and is arranged parallel to the first surface. Since the heating target contacts the first surface over the entire surface, the distance between the heating target mounted on the first surface and the shower head is easily uniformly ensured.

In the heater of the present disclosure, energy is uniformly provided over the entire surface of the heating target, because the thickness of the base body located between the heating target mounted on the first surface and the high frequency electrode is uniformly ensured, and the distance between the heating target mounted on the first surface and the shower head is uniformly ensured. Accordingly, in the heater of the present disclosure, unevenness in film formation on the heating target by plasma treatment is suppressed, when compared with a case where the thickness of the base body or the distance described above is not uniform.
(2) In the heater of the present disclosure, the third flow path may be arranged closer to the second surface than the heating element.

In the form described above, heat transfer from the heating element to the first surface is less likely to be inhibited by the third flow path. Accordingly, in the form described above, the heating target mounted on the first surface is more uniformly heated over the entire surface by the heating element.
(3) In the heater of the present disclosure, a distance between the high frequency electrode and the third flow path in a thickness direction of the base body may be more than or equal to 2 mm.

In the form described above, since the distance is ensured to some extent, occurrence of discharge in a space constituting the third flow path during film formation on the heating target by plasma treatment is more likely to be suppressed.
(4) The heater of the present disclosure may further include a shield electrode arranged inside the base body, wherein the shield electrode may be arranged in a plane that is parallel to the first surface and is located between the high frequency electrode and the third flow path.

In the form described above, since the heater includes the shield electrode, energy is suppressed from being provided to the third flow path. In the form described above, since energy is less likely to be provided to the third flow path, occurrence of discharge in the space constituting the third flow path during film formation on the heating target by plasma treatment is more likely to be suppressed.
(5) In the heater of the present disclosure, the number of the first flow paths may be plural, and the gas intakes may be arranged side by side in a circumferential direction of the base body, in the first surface.

In the form described above, the heating target mounted on the first surface is vacuum-suctioned onto the first surface, over the entire circumference.
(6) In the heater of the present disclosure, the number of the first flow paths may be plural, the number of the second flow paths may be one, a plurality of first gas intakes may be provided as the gas intakes, in the first surface, and lengths from the plurality of first gas intakes, respectively, to the gas exhaust along the first flow paths, the second flow path, and the third flow path may be identical.

In the form described above, the heating target mounted on the first surface is vacuum-suctioned onto the first surface by the plurality of first gas intakes having the same suction force. For example, in the form described above, the heating target mounted on the first surface is uniformly vacuum-suctioned onto the first surface, over the entire circumference.
(7) In the heater of the present disclosure, the number of the first flow paths may be plural, the number of the second flow paths may be one, a second gas intake and a third gas intake may be provided as the gas intakes, in the first surface, and a length from the second gas intake to the gas exhaust along the first flow path, the second flow path, and the third flow path may be different from a length from the third gas intake to the gas exhaust along the first flow path, the second flow path, and the third flow path.

In the form described above, the heating target mounted on the first surface is vacuum-suctioned onto the first surface, at different positions in a radial direction of the base body.
(8) In the heater of the present disclosure, the number of the first flow paths may be plural, the third flow path may include a plurality of branch paths extending radially from a center side of the base body, the second flow path or a plurality of the second flow paths may be connected to the center side of the base body in the third flow path, and at least one of a plurality of the first flow paths may be connected to a tip portion of one of the branch paths.

In the form described above, the heating target mounted on the first surface is uniformly vacuum-suctioned onto the first surface, over the entire circumference.

### DETAILED DESCRIPTION OF EMBODIMENTS OF THE PRESENT DISCLOSURE

Embodiments of the heater of the present disclosure will be described with reference to the drawings. The same reference numerals in the drawings designate identically named parts. It should be noted that the present invention is not limited to these illustrations but is defined by the scope of the claims, and is intended to include any modifications within the scope and meaning equivalent to the scope of the claims.

### <Overall Configuration>

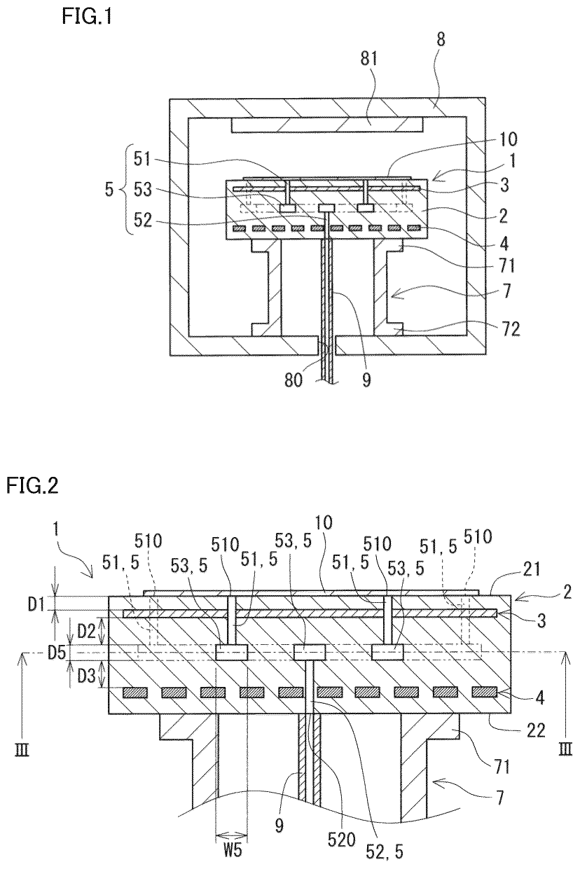

Referring to FIGS. 1 to 3, a heater 1 of an embodiment will be described. Heater 1 is utilized for a film formation device that forms a thin film on a surface of a heating target 10 by plasma treatment. As shown in FIG. 1, heater 1 is arranged within a chamber 8 in which an atmosphere gas can be controlled. Within chamber 8, a shower head 81 is arranged on an upper surface that faces heater 1. A reactive gas used for plasma treatment is injected from shower head 81 toward heater 1. A high frequency transmitter not shown is connected to shower head 81. Shower head 81 also serves as a high frequency electrode.

As shown in FIGS. 1, 2, and 10, heater 1 includes a base body 2, a high frequency electrode 3, a heating element 4, and a support body 7. Heater 1 may further include a shield electrode 6, as shown in FIGS. 11 to 13. High frequency electrode 3, heating element 4, and shield electrode 6 are arranged inside base body 2 to be parallel to one another.

One of the characteristics of heater 1 of the embodiment is that heater 1 includes, in base body 2, a flow path 5 as a component that vacuum-suctions heating target 10 onto base body 2. One of the characteristics of heater 1 of the embodiment is that high frequency electrode 3, heating element 4, and flow path 5 are arranged in a specific order inside base body 2. When heater 1 includes shield electrode 6, shield electrode 6 is also arranged in a specific order inside base body 2.

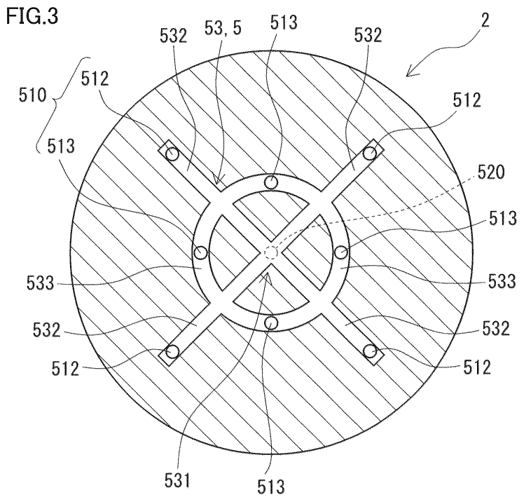

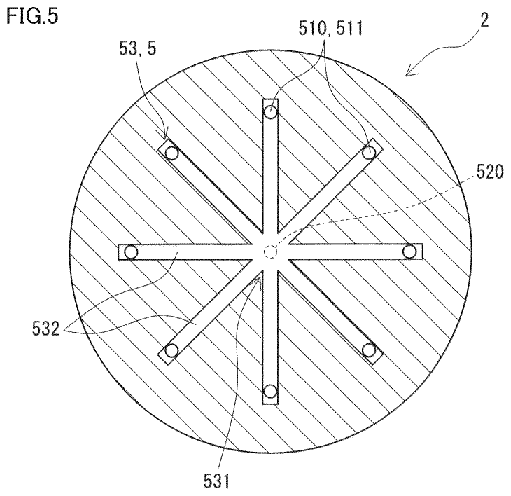

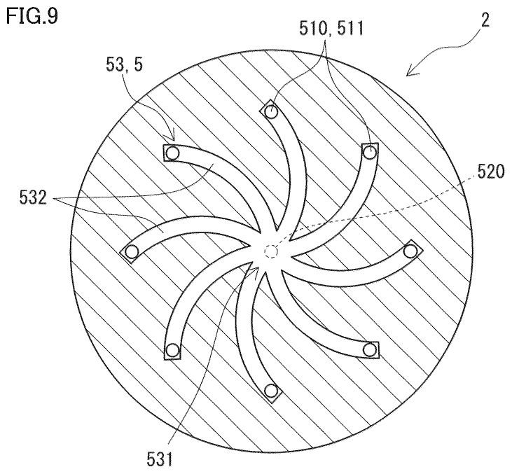

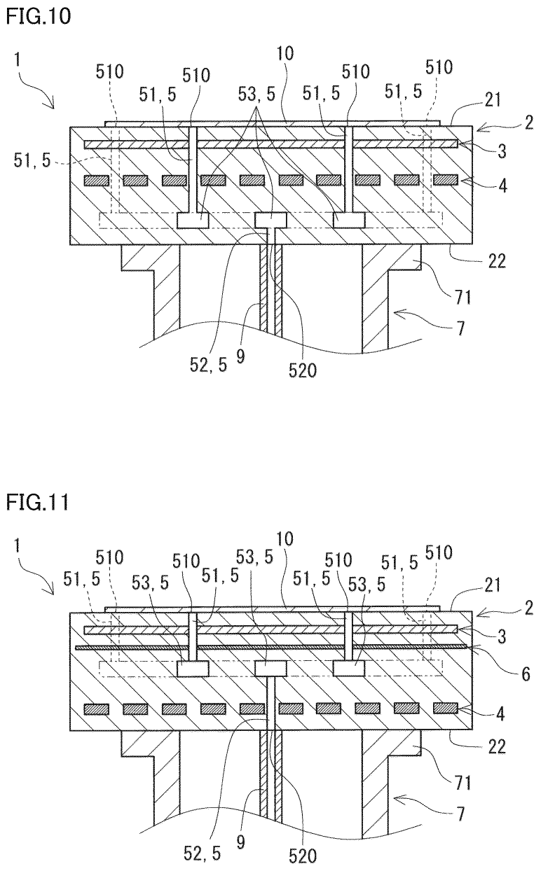

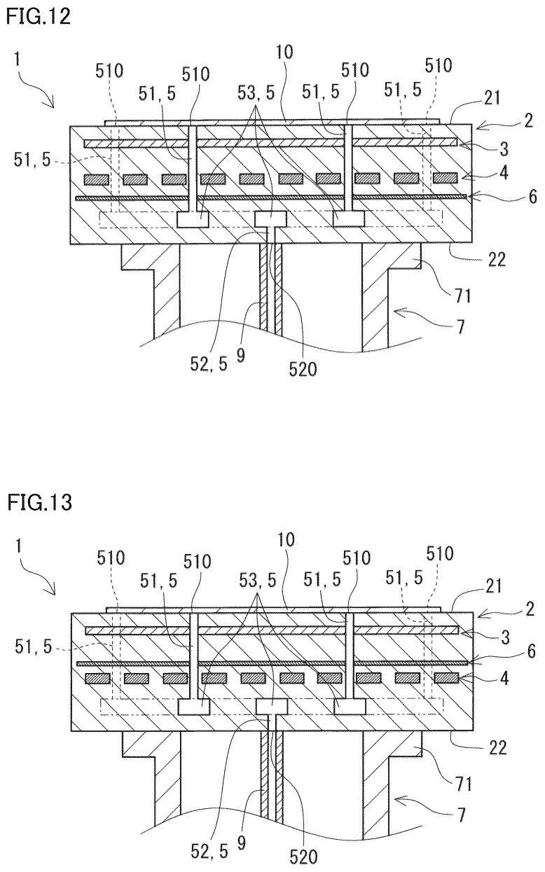

FIGS. 1 to 3 show heater 1 of a first embodiment. FIGS. 4 to 9 show different patterns of a third flow path 53 provided in base body 2 of heater 1. Third flow path 53 is a portion of flow path 5. FIG. 10 shows heater 1 of a second embodiment. In FIG. 10, the order of heating element 4 and third flow path 53 is interchanged, when compared with the order shown in FIG. 2. FIG. 11 shows heater 1 of a third embodiment. In FIG. 11, shield electrode 6 is added to base body 2 shown in FIG. 2. FIG. 12 shows heater 1 of a fourth embodiment. In FIG. 12, shield electrode 6 is added to base body 2 shown in FIG. 10. FIG. 13 shows heater 1 of a fifth embodiment. In FIG. 13, shield electrode 6 is added to base body 2 shown in FIG. 10, at a position different from that in FIG. 12. In each drawing, for easier understanding, high frequency electrode 3, heating element 4, flow path 5, and shield electrode 6 are shown in an exaggerated manner. In each drawing, the size and the like of each of base body 2, high frequency electrode 3, heating element 4, flow path 5, and shield electrode 6 are schematically shown, and do not necessarily correspond to the actual size. In the following, each component will be described in detail for each embodiment.

### First Embodiment

Referring to FIGS. 1 to 3, heater 1 of the first embodiment will be described. As shown in FIGS. 1 and 2, heater 1 of the first embodiment includes base body 2, high frequency electrode 3, heating element 4, and support body 7. In heater 1 of the first embodiment, high frequency electrode 3, third flow path 53 as a portion of flow path 5, and heating element 4 are arranged in order, from a first surface 21 side toward a second surface 22 side, inside base body 2.

### <<Base Body>>

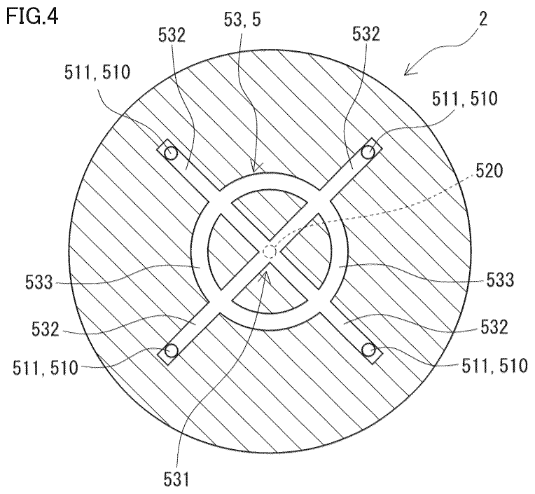

Base body 2 has a disk-shape, as shown in FIG. 3. Base body 2 includes a first surface 21 and a second surface 22, as shown in FIG. 2. First surface 21 and second surface 22 are opposite to each other. Heating target 10 is mounted on first surface 21. Heating target 10 is a wafer of silicon or a compound semiconductor, for example. A first end portion 71 of support body 7 described later is attached to second surface 22. In a region inside support body 7 on the second surface 22 side, there are provided a plurality of holes into which terminals not shown respectively connected to high frequency electrode 3 and heating element 4 described later are fitted. The terminals protrude from second surface 22. For the convenience of description, the terminals and the plurality of holes into which the terminals are fitted are not shown.

Flow path 5 described later is provided inside base body 2. Flow path 5 is provided to connect first surface 21 and second surface 22.

The material for base body 2 is a known ceramic, for example. The ceramic is aluminum nitride, aluminum oxide, or silicon carbide, for example. The material for base body 2 may be a composite material of the ceramic and a metal. The metal is aluminum, an aluminum alloy, copper, or a copper alloy, for example. The material for base body 2 in the present example is aluminum nitride.

### <<High Frequency Electrode>>

High frequency electrode 3 is an electrode that generates plasma between itself and shower head 81 shown in FIG. 1. High frequency electrode 3 is grounded. Alternatively, high frequency electrode 3 is connected to a high frequency transmitter other than the high frequency transmitter connected to shower head 81. High frequency electrode 3 is connected to a power line not shown. The power line includes a grounding wire. The power line is arranged inside support body 7 described later. High frequency power from the high frequency transmitter not shown is provided between shower head 81 and high frequency electrode 3. The reactive gas injected from shower head 81 is ionized by high frequency energy, and attains a plasma state. Due to the reactive gas in the plasma state, a chemical reaction occurs in heating target 10 mounted on first surface 21, and a thin film is formed on heating target 10 according to the reactive gas.

High frequency electrode 3 has a disk-shape. Preferably, high frequency electrode 3 is arranged concentrically with base body 2. High frequency electrode 3 has a size equal to that of heating target 10, for example. High frequency electrode 3 may be slightly larger than heating target 10. High frequency electrode 3 is embedded inside base body 2. High frequency electrode 3 is arranged in a plane parallel to first surface 21. High frequency electrode 3 is located closest to first surface 21 in a thickness direction of base body 2. Heating element 4 and third flow path 53 described later do not exist between high frequency electrode 3 and first surface 21. A distance D1 between high frequency electrode 3 and first surface 21 is about 1 mm, for example.

The material for high frequency electrode 3 is a metal excellent in heat resistance. The metal is one selected from the group consisting of tungsten, a tungsten alloy, molybdenum, a molybdenum alloy, nickel, and a nickel alloy, for example.

The form of high frequency electrode 3 is not particularly specified. For example, high frequency electrode 3 is formed by screen-printing and firing a paste containing powder made of the metal described above. High frequency electrode 3 may be constituted by a plate, a mesh, or fibers.

### <<Heating Element>>

Heating element 4 is a heat source that heats heating target 10 mounted on first surface 21. Heating element 4 heats heating target 10 via base body 2. Heating element 4 is connected to a terminal and a power line not shown. The power line is arranged inside support body 7 described later. Via the power line, power is supplied from a power source not shown to heating element 4.

Heating element 4 is a circuit pattern formed in a plane in base body 2. The circuit pattern is drawn using a belt-like portion including a belt-like thin line. The shape of heating element 4 is not particularly limited. When base body 2 is seen in plan view from the first surface 21 side, the shape of an outer peripheral contour line of heating element 4 is generally circular. The outer peripheral contour line of heating element 4 is constituted by the arrangement of the belt-like portion. Preferably, heating element 4 is arranged concentrically with base body 2. Heating element 4 is also arranged concentrically with high frequency electrode 3.

Heating element 4 is embedded inside base body 2. Heating element 4 is arranged in a plane parallel to first surface 21. Heating element 4 is arranged closer to second surface 22 than high frequency electrode 3.

Heating element 4 is constituted by bending the belt-like portion, for example. Bending of the belt-like portion includes bending in a spiral or serpentine manner. Heating element 4 may include a planar portion with a predetermined shape wider than the belt-like portion. The shape of an outer peripheral contour line of the planar portion is a fan shape or semicircular, for example. The belt-like portion and the planar portion are connected continuously. The circuit pattern of heating element 4 is not particularly limited. The circuit pattern of heating element 4 can be selected as appropriate according to heating temperature and desired temperature distribution.

The material for heating element 4 is not particularly limited, as long as it allows heating element 4 to heat heating target 10 to a desired temperature. The material for heating element 4 is a metal suitable for resistive heating. The metal is one selected from the group consisting of stainless steel, nickel, a nickel alloy, silver, a silver alloy, tungsten, a tungsten alloy, molybdenum, a molybdenum alloy, chromium, and a chromium alloy, for example. The nickel alloy is nichrome, for example.

The form of heating element 4 is not particularly specified. For example, heating element 4 is formed by screen-printing and firing a paste containing powder made of the metal described above. In addition, heating element 4 is formed by patterning a foil made of the metal described above. Instead of the circuit pattern using the belt-like portion, heating element 4 may be a tungsten coil or a molybdenum coil.

### <<Flow Path>>

Flow path 5 is a space provided inside base body 2. As shown in FIG. 2, flow path 5 is provided to be connected to first surface 21 and second surface 22. Flow path 5 includes a first flow path 51, a second flow path 52, and third flow path 53. In FIG. 2, an outline that encompasses third flow path 53 is indicated by a chain double-dashed line. FIG. 3 is a cross sectional view of third flow path 53 shown in FIG. 2 taken along a plane parallel to first surface 21. In FIG. 3, gas intakes 510 provided on the first surface 21 side are indicated by solid lines. In FIG. 3, an gas exhaust 520 provided on the second surface 22 side is imaginarily indicated by a broken line.

### [First Flow Path]

As shown in FIG. 2, first flow path 51 includes gas intake 510 provided on the first surface 21 side. Gas intake 510 in the present example is provided in first surface 21. When a wafer pocket not shown is provided in base body 2, a bottom surface of the wafer pocket is first surface 21, and gas intake 510 is provided in first surface 21. When a groove not shown is provided in first surface 21, a plurality of gas intakes 510 may be provided in a bottom surface of the groove.

Flow path 5 in the present example includes a plurality of first flow paths 51. In first surface 21 shown in FIG. 2, the plurality of gas intakes 510 are arranged as shown in FIG. 3. Gas intakes 510 are covered with heating target 10 mounted on first surface 21. Preferably, the plurality of gas intakes 510 are arranged side by side in a circumferential direction of base body 2, in first surface 21. In particular, preferably, the plurality of gas intakes 510 are arranged side by side at regular intervals in the circumferential direction of base body 2, in first surface 21 (FIG. 2). The plurality of gas intakes 510 may be arranged on circumferences with different diameters in base body 2, in the first surface (FIG. 2). In the present example, four gas intakes 510 are arranged on each of two circumferences with different diameters in base body 2.

The shape of an opening of gas intake 510 is not particularly specified. The shape of the opening of gas intake 510 in the present example is circular.

First flow path 51 extends from each gas intake 510 toward the inside of base body 2. First flow path 51 extends in a direction crossing first surface 21. First flow path 51 in the present example extends in a direction perpendicular to first surface 21.

The shape of a cross section of first flow path 51 is not particularly specified. The shape of the cross section of first flow path 51 in the present example is circular, as with the shape of the opening of gas intake 510. The cross section of first flow path 51 is a cross section taken in a direction perpendicular to the direction in which first flow path 51 extends.

The area of the cross section of first flow path 51 can be selected as appropriate to such an extent that a good gas flowability can be ensured. A gas is a reactive gas, for example. The total area of the cross sections of first flow paths 51 is more than or equal to 0.2 mm² and less than or equal to 2500 mm², for example, and preferably more than or equal to 15 mm² and less than or equal to 500 mm². When the total area of the cross sections of first flow paths 51 is more than or equal to a lower limit, a good gas flowability is ensured. When the total area of the cross sections of first flow paths 51 is less than or equal to an upper limit, inhibition of heat transfer from heating element 4 by first flow path 51 is more likely to be suppressed. The area of the cross section of each first flow path 51 is selected as appropriate such that the total area of a plurality of cross sections may satisfy the range described above.

The cross section of first flow path 51 in the present example has a shape and a size that are uniform in the direction in which first flow path 51 extends. The shape of the cross section of first flow path 51 may change in the middle of the direction in which first flow path 51 extends. The area of the cross section of first flow path 51 may change in the middle of the direction in which first flow path 51 extends.

When the plurality of first flow paths 51 are provided, the cross sections of first flow paths 51 may have the same shape and size, or may have different shapes and sizes. When first flow paths 51 are provided such that gas intakes 510 are arranged on the circumferences with different diameters in base body 2 in first surface 21, some first flow paths 51 are located on a circumference with a smaller diameter, and the other first flow paths 51 are located on a circumference with a larger diameter. In first flow paths 51 located on the circumference with the smaller diameter and first flow paths 51 located on the circumference with the larger diameter, at least one of the shape and the size of the cross sections of first flow paths 51 may be different.

### [Second Flow Path]

As shown in FIG. 2, second flow path 52 includes gas exhaust 520 provided in the region inside support body 7 in second surface 22. Gas exhaust 520 in the present example is provided in second surface 22. When second surface 22 is provided with a protrusion locally protruding or a recess locally recessed from the surface to which support body 7 is attached, gas exhaust 520 may be provided in an end surface of the protrusion or a bottom surface of the recess. A suction pipe 9 is connected to gas exhaust 520. A vacuum pump not shown is connected to suction pipe 9. By the suction of the vacuum pump, the inside of flow path 5 is decompressed via suction pipe 9. Suction pipe 9 is arranged inside support body 7 described later.

Flow path 5 in the present example includes one second flow path 52. In second surface 22 shown in FIG. 2, one gas exhaust 520 is arranged as shown in FIG. 3. Preferably, gas exhaust 520 is arranged on a center side of base body 2 in second surface 22. Gas exhaust 520 in the present example is provided concentrically with the center of base body 2.

The shape of an opening of gas exhaust 520 is not particularly specified. The shape of the opening of gas exhaust 520 in the present example is circular.

Second flow path 52 extends from gas exhaust 520 toward the inside of base body 2. Second flow path 52 extends in a direction crossing second surface 22. Second flow path 52 in the present example extends in a direction perpendicular to second surface 22. In the present example, the direction in which first flow path 51 extends and the direction in which second flow path 52 extends are parallel to each other, and are parallel to an axial direction of base body 2.

The shape of a cross section of second flow path 52 is not particularly specified. The shape of the cross section of second flow path 52 in the present example is circular, as with the shape of the opening of gas exhaust 520. The cross section of second flow path 52 is a cross section taken in a direction perpendicular to the direction in which second flow path 52 extends. The area of the cross section of second flow path 52 can be selected as appropriate to such an extent that a good gas flowability can be ensured. For example, the area of the cross section of second flow path 52 is more than or equal to 0.2 mm² and less than or equal to 50 mm², and preferably more than or equal to 2 mm² and less than or equal to 20 mm². When the area of the cross section of second flow path 52 is more than or equal to a lower limit, a good gas flowability is ensured. When the area of the cross section of second flow path 52 is less than or equal to an upper limit, the arrangement of heating element 4 and heat transfer are less likely to be inhibited, even though heating element 4 is arranged closer to second surface 22 than third flow path 53.

The cross section of second flow path 52 in the present example has a shape and a size that are uniform in the direction in which second flow path 52 extends. The shape of the cross section of second flow path 52 may change in the middle of the direction in which second flow path 52 extends. The area of the cross section of second flow path 52 may change in the middle of the direction in which second flow path 52 extends.

### [Third Flow Path]

As shown in FIG. 2, third flow path 53 connects first flow path 51 and second flow path 52. Third flow path 53 is arranged in a plane parallel to first surface 21. Third flow path 53 extends along the plane parallel to first surface 21. Third flow path 53 is arranged closer to second surface 22 than high frequency electrode 3. A distance D2 between high frequency electrode 3 and third flow path 53 in the thickness direction of base body 2 is more than or equal to 2 mm, for example. When distance D2 is more than or equal to 2 mm, occurrence of discharge in a space constituting third flow path 53 during film formation on heating target 10 by plasma treatment is more likely to be suppressed. Distance D2 is less than or equal to 12 mm, for example. When distance D2 is less than or equal to 12 mm, thickening of base body 2 is more likely to be suppressed. Distance D2 is more than or equal to 2 mm and less than or equal to 12 mm, for example, and further, is more than or equal to 4 mm and less than or equal to 8 mm.

Third flow path 53 in the present example is arranged closer to first surface 21 than heating element 4. That is, third flow path 53 in the present example is arranged in a plane between high frequency electrode 3 and heating element 4. A distance D3 between heating element 4 and third flow path 53 in the thickness direction of base body 2 is more than or equal to 2 mm, for example. When distance D3 is more than or equal to 2 mm, the thickness of base body 2 located between heating element 4 and third flow path 53 can be ensured to some extent, and heat transfer property from heating element 4 via base body 2 is more likely to be ensured. Distance D3 is less than or equal to 12 mm, for example. When distance D3 is less than or equal to 12 mm, thickening of base body 2 is more likely to be suppressed. Distance D3 is more than or equal to 2 mm and less than or equal to 12 mm, for example, and further, is more than or equal to 4 mm and less than or equal to 8 mm.

Preferably, third flow path 53 includes a central portion 531 and a plurality of branch paths 532, as shown in FIG. 3. Third flow path 53 in the present example further includes a circular path 533 that connects midpoints in directions in which branch paths 532 extend. In the present example, second gas intakes 512 and third gas intakes 513 are provided as gas intakes 510.

Central portion 531 is arranged at substantially the center of base body 2. Second flow path 52 shown in FIG. 2 is connected to central portion 531. That is, gas exhaust 520 is arranged at substantially the center of base body 2.

Branch paths 532 are arranged to extend radially from central portion 531. Branch paths 532 have the same length. The length of branch paths 532 is a length that reaches a peripheral edge portion of heating target 10. In the present example, four branch paths 532 are arranged. Four branch paths 532 are arranged side by side at regular intervals in the circumferential direction of base body 2. First flow path 51 shown in FIG. 2 is connected to a tip portion of each branch path 532. Since first flow paths 51 are connected to the tip portions of the plurality of branch paths 532, first surface 21 shown in FIG. 2 is provided with a plurality of second gas intakes 512 shown in FIG. 3 as gas intakes 510. The plurality of second gas intakes 512 are arranged side by side on a circumference with a single diameter in base body 2, in first surface 21. Lengths from respective second gas intakes 512 to gas exhaust 520 along first flow paths 51, second flow path 52, and third flow path 53 are identical.

First flow path 51 shown in FIG. 2 is connected to between adjacent branch paths 532 in circular path 533. Since first flow paths 51 are connected to circular path 533 that connects the midpoints in the directions in which branch paths 532 extend, first surface 21 shown in FIG. 2 is provided with third gas intakes 513 shown in FIG. 3 as gas intakes 510. A plurality of third gas intakes 513 are arranged side by side on a circumference with a single diameter in base body 2, in first surface 21. Lengths from respective third gas intakes 513 to gas exhaust 520 along first flow paths 51, second flow path 52, and third flow path 53 are identical.

Second gas intakes 512 and third gas intakes 513 are arranged on respective circumferences with different diameters in base body 2, in first surface 21. A length from each second gas intake 512 to gas exhaust 520 along first flow path 51, second flow path 52, and third flow path 53 is different from a length from each third gas intake 513 to gas exhaust 520 along first flow path 51, second flow path 52, and third flow path 53.

The shape of a cross section of third flow path 53 is not particularly specified. The shape of the cross section of third flow path 53 in the present example is rectangular. The cross section of third flow path 53 is a cross section taken in a direction perpendicular to a direction in which third flow path 53 extends.

The area of the cross section of third flow path 53 can be selected as appropriate to such an extent that a good gas flowability can be ensured. A depth D5 (see FIG. 2) of third flow path 53 is more than or equal to 0.2 mm and less than or equal to 8 mm, for example, and preferably more than or equal to 0.4 mm and less than or equal to 3 mm. A width W5 (see FIG. 2) of third flow path 53 is more than or equal to 0.5 mm and less than or equal to 20 mm, for example, and preferably more than or equal to 1 mm and less than or equal to 6 mm.

The cross section of third flow path 53 in the present example has a shape and a size that are uniform in the direction in which third flow path 53 extends. The shape of the cross section of third flow path 53 may change in the middle of the direction in which third flow path 53 extends. The area of the cross section of third flow path 53 may change in the middle of the direction in which third flow path 53 extends. Preferably, the area, depth D5, and width W5 described above are satisfied, even if the shape or the area of the cross section of third flow path 53 changes in the middle of the direction in which third flow path 53 extends.

The total area of the cross section of third flow path 53 taken along the plane parallel to first surface 21 is more than or equal to 500 mm² and less than or equal to 30000 mm², for example, and preferably more than or equal to 1500 mm² and less than or equal to 10000 mm². When the total area of the cross section is more than or equal to a lower limit, a good gas flowability is ensured. When the total area of the cross section is less than or equal to an upper limit, inhibition of heat transfer from heating element 4 by third flow path 53 is more likely to be suppressed, even though heating element 4 is arranged closer to second surface 22 than third flow path 53.

When base body 2 is seen in plan view from the first surface 21 side, the overlapping area of third flow path 53 and heating element 4 is preferably small. In particular, when third flow path 53 is arranged closer to first surface 21 than heating element 4 as in the present example, the overlapping area is preferably smaller. The smaller the overlapping area is, the more the inhibition of heat transfer from heating element 4 by third flow path 53 is likely to be suppressed.

Flow path 5 can be manufactured through the following procedure, for example. First, a first plate including high frequency electrode 3 arranged inside, a second plate including heating element 4 arranged inside, and a third plate provided with flow path 5 are fabricated individually. For the first plate including high frequency electrode 3 arranged inside, for example, high frequency electrode 3 formed by screen-printing and firing a paste containing powder made of tungsten metal as described above is used. For the second plate including heating element 4 arranged inside, for example, heating element 4 formed by screen-printing and firing a paste containing powder made of tungsten metal as described above is used. Although not shown, a boundary between the first plate and the third plate is located between high frequency electrode 3 and third flow path 53 shown in FIG. 2. A boundary between the second plate and the third plate is located between heating element 4 and third flow path 53 shown in FIG. 2. In the first plate, first flow paths 51 are formed according to the shape of flow path 5 in the third plate. In the second plate, second flow path 52 is formed according to the shape of flow path 5 in the third plate. Finally, the plates are stacked in order of the first plate, the third plate, and the second plate, and are joined.

Base body 2 manufactured through the procedure described above includes a third surface in which high frequency electrode 3 is arranged, a fourth surface in which heating element 4 is arranged, and a fifth surface in which third flow path 53 is arranged. The third surface, the fourth surface, and the fifth surface are planes parallel to first surface 21. In the present example, the third surface, the fifth surface, and the fourth surface are located in order, from the first surface 21 side toward the second surface 22 side.

### <<Support Body>>

Support body 7 supports base body 2 from the second surface 22 side, as shown in FIGS. 1 and 2. Support body 7 has a cylindrical shape. The shape of support body 7 is not particularly specified. Support body 7 in the present example is a cylindrical member. Support body 7 is arranged concentrically with base body 2. In the present example, base body 2 and support body 7 are connected such that the center of cylindrical support body 7 is arranged coaxially with the center of circular plate-like base body 2. Support body 7 is connected to base body 2 to surround the power line connected to high frequency electrode 3, the power line connected to heating element 4, and suction pipe 9 connected to flow path 5.

Support body 7 includes first end portion 71 and a second end portion 72. Each of first end portion 71 and second end portion 72 has the shape of a flange bending outward. First end portion 71 is attached to second surface 22. A seal member not shown is arranged between first end portion 71 and second surface 22. Second end portion 72 is attached to a bottom surface of chamber 8. A seal member not shown is arranged between second end portion 72 and the bottom surface of chamber 8. Airtightness inside support body 7 is maintained by these seal members. As long as airtightness can be maintained, at least one of a portion between first end portion 71 and second surface 22 and a portion between second end portion 72 and the bottom surface of chamber 8 may be directly joined, without a seal member being arranged therebetween. Typically, a corrosive gas is charged into chamber 8 in which heater 1 is arranged. By maintaining airtightness inside support body 7, the power lines not shown and suction pipe 9 arranged inside support body 7 can be isolated from the corrosive gas. A through hole 80 is provided in the region inside support body 7 in the bottom surface of chamber 8. The power lines not shown and suction pipe 9 are drawn out of chamber 8 via through hole 80.

The material for support body 7 is the same ceramic as the material for base body 2, for example. The material for support body 7 may be the same as or different from the material for base body 2.

In heater 1 of the first embodiment, heating target 10 mounted on first surface 21 is vacuum-suctioned onto first surface 21 by flow path 5 provided in base body 2. In particular, since the plurality of gas intakes 510 are arranged side by side at regular intervals on the circumferences with different diameters in base body 2, heating target is uniformly vacuum-suctioned onto first surface 21, over the entire surface. By this vacuum suction, even if heating target 10 has warpage before being mounted on first surface 21, the warpage is corrected. Further, even if warpage almost occurs due to heat or a chemical reaction during film formation on heating target 10, the warpage is corrected. Since the warpage is corrected, heating target 10 mounted on first surface 21 can contact first surface 21, over the entire surface.

Since heating element 4 is arranged in a plane parallel to first surface 21 in base body 2, heating target 10 is uniformly heated over the entire surface by heating element 4.

Since high frequency electrode 3 is located closest to first surface 21 in the thickness direction of base body 2, and is arranged in a plane parallel to first surface 21, the thickness of base body 2 located between heating target 10 and high frequency electrode 3 is uniformly ensured. Further, since shower head 81 is arranged parallel to first surface 21, the distance between heating target 10 and shower head 81 is uniformly ensured. Therefore, energy is uniformly provided over the entire surface of heating target 10, suppressing unevenness in film formation on heating target 10 by plasma treatment.

### VARIATIONS

The form of flow path 5 can be changed as appropriate as long as flow path 5 is connected to first surface 21 and second surface 22 and can vacuum-suction heating target 10 mounted on first surface 21 onto first surface 21. Mainly, the form of third flow path 53 can be changed, for example, as in first to sixth variations described below. First flow paths 51 and second flow path 52 are arranged corresponding to third flow path 53. FIGS. 4 to 9 are each a cross sectional view of third flow path 53 taken along a plane parallel to first surface 21, as in FIG. 3. In FIGS. 4 to 9, gas intakes 510 provided on the first surface 21 side shown in FIG. 2 are indicated by solid lines. In FIGS. 4 to 9, gas exhaust 520 provided on the second surface 22 side shown in FIG. 2 is imaginarily indicated by a broken line. In the description of the first variation, FIG. 2 is also referred to as necessary.

### First Variation

As shown in FIG. 4, third flow path 53 of the first variation includes a plurality of branch paths 532 and circular path 533, as with third flow path 53 of the first embodiment. Third flow path 53 of the first variation is different from third flow path 53 of the first embodiment in that circular path 533 is not connected to first flow paths 51 shown in FIG. 2. First flow path 51 shown in FIG. 2 is connected to the tip portion of each branch path 532. In the present example, a plurality of first gas intakes 511 are provided as gas intakes 510.

In flow path 5 of the first variation, lengths from first gas intakes 511 to gas exhaust 520 along first flow paths 51, second flow path 52, and third flow path 53 are all identical. Flow path 5 of the first variation is simple because circular path 533 is not connected to first flow paths 51 shown in FIG. 2.

### Second Variation

As shown in FIG. 5, third flow path 53 of the second variation includes a plurality of linear branch paths 532 extending radially from central portion 531. In the present example, eight branch paths 532 are arranged. Eight branch paths 532 are arranged side by side at regular intervals in the circumferential direction of base body 2. Branch paths 532 have the same length. The length of branch paths 532 is a length that reaches the peripheral edge portion of heating target 10 shown in FIG. 2. Second flow path 52 shown in FIG. 2 is connected to central portion 531. First flow path 51 shown in FIG. 2 is connected to the tip portion of each branch path 532. In the present example, a plurality of first gas intakes 511 are provided as gas intakes 510.

When compared with third flow path 53 of the first embodiment, third flow path 53 of the second variation includes more branch paths 532, and does not include circular path 533 shown in FIG. 3.

In flow path 5 of the second variation, more first gas intakes 511 are arranged in the peripheral edge portion of heating target 10. In flow path 5 of the second variation, lengths from first gas intakes 511 to gas exhaust 520 along first flow paths 51, second flow path 52, and third flow path 53 are all identical. Therefore, in flow path 5 of the second variation, the peripheral edge portion of heating target 10 is easily uniformly vacuum-suctioned in a circumferential direction of first surface 21. Flow path 5 of the second variation is simple because it is constituted by linear branch paths 532.

### Third Variation

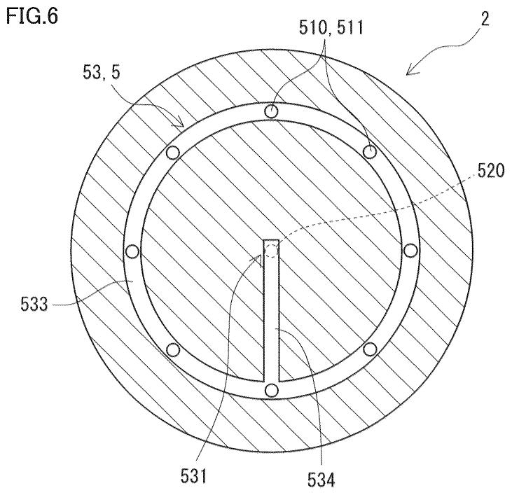

As shown in FIG. 6, third flow path 53 of the third variation includes circular path 533 and a connection path 534. Circular path 533 is a circular flow path provided to face the peripheral edge portion of heating target 10 shown in FIG. 2. Connection path 534 connects central portion 531 and circular path 533. The number of connection paths 534 is one.

In flow path 5 of the third variation, as gas intakes 510, a plurality of first gas intakes 511 are arranged at regular intervals along circular path 533. In flow path 5 of the third variation, third flow path 53 arranged in a central region of base body 2 is smaller, when compared with the first embodiment and the like. Therefore, in flow path 5 of the third variation, heat transfer from heating element 4 is less likely to be inhibited by third flow path 53.

### Fourth Variation

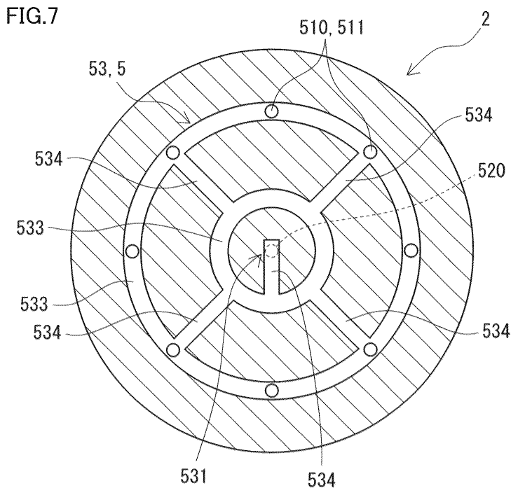

As shown in FIG. 7, third flow path 53 of the fourth variation includes two circular paths 533 with different diameters and a plurality of connection paths 534. Of two circular paths 533, circular path 533 with a larger diameter is a circular flow path provided to face the peripheral edge portion of heating target 10 shown in FIG. 2. Of two circular paths 533, circular path 533 with a smaller diameter is a circular flow path provided to face an annular portion between a central portion and the peripheral edge portion of heating target 10 shown in FIG. 2. One of the plurality of connection paths 534 connects central portion 531 and circular path 533 with the smaller diameter. The remaining four of the plurality of connection paths 534 connect circular path 533 with the smaller diameter and circular path 533 with the larger diameter.

In flow path 5 of the fourth variation, as gas intakes 510, a plurality of first gas intakes 511 are arranged at regular intervals along circular path 533 with the larger diameter. In flow path 5 of the fourth variation, gas flowability through third flow path 53 is more likely to be ensured, when compared with the third variation.

### Fifth Variation

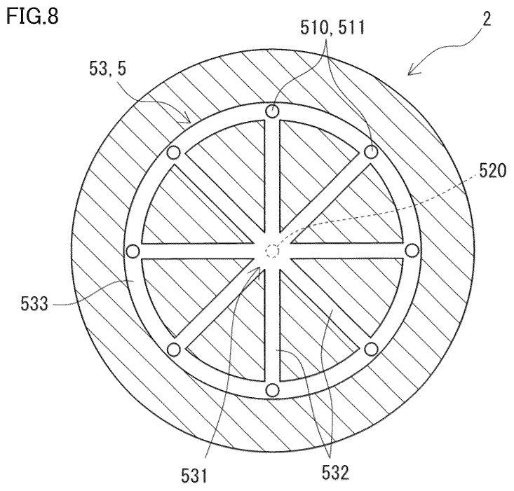

As shown in FIG. 8, third flow path 53 of the fifth variation further includes circular path 533, when compared with third flow path 53 of the second variation shown in FIG. 5. Circular path 533 is provided to connect the tip portions of the plurality of branch paths 532. In flow path 5 of the fifth variation, gas flowability through third flow path 53 is more likely to be ensured, when compared with the second variation.

### Sixth Variation

As shown in FIG. 9, third flow path 53 of the sixth variation includes a plurality of curved branch paths 532 extending radially from central portion 531. Third flow path 53 of the sixth variation is different from third flow path 53 of the second variation in that branch paths 532 are curved, and is otherwise the same as third flow path 53 of the second variation. In flow path 5 of the sixth variation, the peripheral edge portion of heating target 10 is easily uniformly vacuum-suctioned in the circumferential direction of first surface 21, as with flow path 5 of the second variation. In flow path 5 of the sixth variation, flow resistance can be easily adjusted by adjusting the degree of curvature of curved lines, when compared with the second variation.

### Second Embodiment

Referring to FIG. 10, heater 1 of a second embodiment will be described. In heater 1 of the second embodiment, the order of heating element 4 and third flow path 53 is interchanged, when compared with heater 1 of the first embodiment. In heater 1 of the first embodiment, third flow path 53 is arranged closer to second surface 22 than heating element 4. In heater 1 of the second embodiment, high frequency electrode 3, heating element 4, and third flow path 53 are arranged in order, from the first surface 21 side toward the second surface 22 side, inside base body 2. Heater 1 of the second embodiment has the same configuration as that of heater 1 of the first embodiment except that the order of heating element 4 and third flow path 53 is interchanged.

The distance between high frequency electrode 3 and heating element 4 in the thickness direction of base body 2 is more than or equal to 2 mm and less than or equal to 12 mm, for example, and further, is more than or equal to 4 mm and less than or equal to 8 mm. The distance between heating element 4 and third flow path 53 in the thickness direction of base body 2 is more than or equal to 2 mm and less than or equal to 12 mm, for example, and further, is more than or equal to 4 mm and less than or equal to 8 mm.

Heater 1 of the second embodiment exhibits the same effect as that of heater 1 of the first embodiment. In heater 1 of the second embodiment, since third flow path 53 is arranged closer to second surface 22 than heating element 4, third flow path 53 does not exist between heating element 4 and first surface 21. That is, the thickness of base body 2 located between heating target 10 mounted on first surface 21 and heating element 4 is easily uniformly ensured. Accordingly, in heater 1 of the second embodiment, inhibition of heat transfer from heating element 4 by third flow path 53 is further likely to be suppressed, when compared with heater 1 of the first embodiment. In other words, in heater 1 of the second embodiment, heat transfer to heating target 10 via base body 2 is easily uniformly performed in a radial direction and the circumferential direction of base body 2, when compared with heater 1 of the first embodiment.

### Third Embodiment

Referring to FIG. 11, heater 1 of a third embodiment will be described. Heater 1 of the third embodiment further includes shield electrode 6 arranged inside base body 2, when compared with heater 1 of the first embodiment. Heater 1 of the third embodiment has the same configuration as that of heater 1 of the first embodiment, except that it further includes shield electrode 6.

### <<Shield Electrode>>

Shield electrode 6 is arranged in a plane that is parallel to first surface 21 and is located between high frequency electrode 3 and third flow path 53. In the present example, high frequency electrode 3, shield electrode 6, third flow path 53, and heating element 4 are arranged in order, from the first surface 21 side toward the second surface 22 side, inside base body 2. In base body 2, discharge is likely to occur in third flow path 53, because volume resistivity of base body 2 may be reduced due to heating by heating element 4, depending on the material constituting base body 2, and the inside of flow path 5 is decompressed. Shield electrode 6 has a function of suppressing occurrence of discharge in third flow path 53. Shield electrode 6 also has a function of suppressing the influence of high frequency noise on heating element 4. Shield electrode 6 is grounded. Shield electrode 6 is connected to a power line not shown. The power line passes through the inside of support body 7 and is drawn out of chamber 8.

Shield electrode 6 has a disk-shape. Shield electrode 6 has a diameter larger than that of high frequency electrode 3. Shield electrode 6 is embedded inside base body 2. The distance between shield electrode 6 and high frequency electrode 3 in the thickness direction of base body 2 is more than or equal to 1 mm and less than or equal to 12 mm, for example, and further, is more than or equal to 2 mm and less than or equal to 8 mm. The distance between shield electrode 6 and third flow path 53 in the thickness direction of base body 2 is more than or equal to 1 mm and less than or equal to 12 mm, for example, and further, is more than or equal to 2 mm and less than or equal to 8 mm.

Furthermore, shield electrode 6 may also be arranged in the thickness direction of base body 2 to face side portions of third flow path 53.

The material for shield electrode 6 is the same metal as that for high frequency electrode 3, for example. The material for shield electrode 6 may be the same as or different from the material for high frequency electrode 3.

Heater 1 of the third embodiment exhibits the same effect as that of heater 1 of the first embodiment. Since heater 1 of the third embodiment further includes shield electrode 6, occurrence of discharge in the space constituting third flow path 53 is suppressed. When discharge occurs in the space constituting third flow path 53, film formation property is degraded by energy loss. In addition, when discharge occurs in the space constituting third flow path 53, a damage occurs in base body 2, and the life of heater 1 is reduced. In heater 1 of the third embodiment, by suppressing the discharge described above, film formation property is improved, and further, reduction of the life of heater 1 is suppressed, when compared with heater 1 of the first embodiment.

### Fourth Embodiment

Referring to FIG. 12, heater 1 of a fourth embodiment will be described. Heater 1 of the fourth embodiment further includes shield electrode 6 arranged inside base body 2, when compared with heater 1 of the second embodiment. Heater 1 of the fourth embodiment has the same configuration as that of heater 1 of the second embodiment, except that it further includes shield electrode 6. The configuration of shield electrode 6 is the same as the configuration of shield electrode 6 in heater 1 of the third embodiment.

In the present example, high frequency electrode 3, heating element 4, shield electrode 6, and third flow path 53 are arranged in order, from the first surface 21 side toward the second surface 22 side, inside base body 2. The distance between shield electrode 6 and heating element 4 in the thickness direction of base body 2 is more than or equal to 1 mm and less than or equal to 12 mm, for example, and further, is more than or equal to 2 mm and less than or equal to 8 mm.

In heater 1 of the fourth embodiment, occurrence of discharge in the space constituting third flow path 53 is suppressed, and thereby film formation property is improved, and further, reduction of the life of heater 1 is suppressed, as with heater 1 of the third embodiment.

### Fifth Embodiment

Referring to FIG. 13, heater 1 of a fifth embodiment will be described. In heater 1 of the fifth embodiment, shield electrode 6 is located at a different position, when compared with heater 1 of the fourth embodiment. Heater 1 of the fifth embodiment has the same configuration as that of heater 1 of the fourth embodiment, except for the position of shield electrode 6.

In the present example, high frequency electrode 3, shield electrode 6, heating element 4, and third flow path 53 are arranged in order, from the first surface 21 side toward the second surface 22 side, inside base body 2. The distance between high frequency electrode 3 and shield electrode 6 in the thickness direction of base body 2 is more than or equal to 1 mm and less than or equal to 12 mm, for example, and further, is more than or equal to 2 mm and less than or equal to 8 mm. The distance between shield electrode 6 and heating element 4 in the thickness direction of base body 2 is more than or equal to 1 mm and less than or equal to 12 mm, for example, and further, is more than or equal to 2 mm and less than or equal to 8 mm.

In heater 1 of the fifth embodiment, occurrence of discharge in the space constituting third flow path 53 is suppressed, as with heater 1 of the fourth embodiment. By suppressing the discharge, film formation property is improved, and further, reduction of the life of heater 1 is suppressed.

### First Test Example

In a first test example, a flow path was provided in a base body, and influences of the arrangement of the flow path on the heating uniformity for a heating target and the film formation property for the heating target were investigated.

### <<Test Pieces>>

The following test pieces 1-1, 1-2, 1-3, and 1-4 were prepared. Any of these test pieces included a high frequency electrode and a heating element inside a base body. Test pieces 1-1, 1-2, and 1-3 further included a flow path inside the base body. Test piece 1-4 did not include a flow path inside the base body. Test pieces 1-1, 1-2, and 1-3 had different orders of arranging the high frequency electrode, the heating element, and a third flow path as a portion of the flow path. In any of these test pieces, the material for the base body, and the shape and the size of the base body were identical. In any of these test pieces, the material for the high frequency electrode, and the shape and the size of the high frequency electrode were identical. In any of these test pieces, the material for the heating element, and the shape and the size of the heating element were identical. In test pieces 1-1, 1-2, and 1-3, the shape and the size of the third flow path were identical. The orders of arranging the high frequency electrode, the heating element, and the third flow path in the respective test pieces were as described below.

In test piece 1-1, the high frequency electrode, the third flow path, and the heating element were arranged in order, from a side of the first surface toward a side of the second surface of the base body. Test piece 1-1 was the same as heater 1 shown in FIG. 2.

In test piece 1-2, the high frequency electrode, the heating element, and the third flow path were arranged in order, from the side of the first surface toward the side of the second surface of the base body. Test piece 1-2 was the same as heater 1 shown in FIG. 10.

In test piece 1-3, the third flow path, the high frequency electrode, and the heating element were arranged in order, from the side of the first surface toward the side of the second surface of the base body.

In test piece 1-4, the high frequency electrode and the heating element were arranged in order, from the side of the first surface toward the side of the second surface of the base body.

In the arrangement orders shown in Table 1, the left side indicates the side of the first surface, and the right side indicates the side of the second surface.

In each test piece, temperature distribution with a heating target being mounted on a first surface of the base body was determined by simulation.

### <<Heating Uniformity>>

Power was supplied to the heating element under a condition that the temperature was increased from ordinary temperature to 500° C. and was maintained for five hours. Then, a plurality of measurement points were set in the heating target, and temperatures at the measurement points were determined. The plurality of measurement points were provided at a central point of the heating target and in a peripheral edge portion of the heating target at regular intervals in a circumferential direction. A difference between the highest temperature and the lowest temperature at the plurality of measurement points was determined. The smaller the difference was, the more the test piece was excellent in heating uniformity. Evaluations of heating uniformity shown in Table 1 are as follows. “AA” indicates that the difference was substantially zero, and the test piece was significantly excellent in heating uniformity. “A” indicates that, although there was a difference, the difference was small, and the test piece was excellent in heating uniformity. “B” indicates that the difference was large, and the test piece was inferior in heating uniformity. “C” indicates that the difference was significantly large, and the test piece was significantly inferior in heating uniformity. The evaluation of heating uniformity was capable of being evaluated based on temperature values measured at 17 measurement points, for example, using a known wafer thermometer.

### <<Film Formation Property>>

A thin film was formed on the heating target by plasma treatment, and a difference between the thickest thickness and the thinnest thickness of the thin film, at the plurality of measurement points provided at the central point of the heating target and in the peripheral edge portion of the heating target at regular intervals in the circumferential direction, was determined. The smaller the difference was, the more the test piece was excellent in film formation property. Evaluations of film formation property shown in Table 1 are as follows. “A” indicates that the difference was small, and the test piece was excellent in film formation property. “C” indicates that the difference was significantly large, and the test piece was significantly inferior in film formation property. The evaluation of film formation property was capable of being measured at 49 measurement points, for example, using a known film thickness meter.

TABLE 1

| | | | Film |
|---|---|---|---|
| Test | | Heating | Formation |
| Piece | Arrangement Order | Uniformity | Property |
| 1-1 | high frequency electrode-third flow path-heating element | A | A |
| 1-2 | high frequency electrode-heating element-third flow path | AA | A |
| 1-3 | third flow path-high frequency electrode-heating element | B | C |
| 1-4 | high frequency electrode-heating element | C | C |

### <<As to Heating Uniformity>>

As shown in Table 1, test pieces 1-1 and 1-2, in which the high frequency electrode was located closest to the first surface in a thickness direction in the base body and which included the flow path, were excellent in heating uniformity. It is conceivable that, in test pieces 1-1 and 1-2, the heating target was vacuum-suctioned onto the first surface of the base body by the flow path, and thereby the heating target was capable of contacting the first surface, over the entire surface. Accordingly, it is conceivable that, in test pieces 1-1 and 1-2, the heating target was capable of being uniformly heated over the entire surface. In particular, in test piece 1-2, since the third flow path was located closer to the second surface than the heating element, test piece 1-2 was significantly excellent in heating uniformity. It is conceivable that, in test piece 1-2, since the third flow path did not exist between the heating element and the first surface, the thickness of the base body located between the heating target mounted on the first surface and the heating element was uniformly ensured, and heat transfer from the heating element was less likely to be inhibited by the third flow path.

Test piece 1-3, in which the third flow path was located closest to the first surface in the thickness direction in the base body, was inferior in heating uniformity. It is conceivable that, in test piece 1-3, since the third flow path was too close to the first surface, test piece 1-3 was significant influenced by inhibition of heat transfer by the third flow path. Test piece 1-4, which did not include a flow path, was significantly inferior in heating uniformity. It is conceivable that, since test piece 1-4 did not include a flow path, warpage of the heating target was not corrected, and the heating target was not capable of contacting the first surface, over the entire surface.

### <<As to Film Formation Property>>

As shown in Table 1, test pieces 1-1 and 1-2, in which the high frequency electrode was located closest to the first surface in the thickness direction in the base body and which included the flow path, were excellent in film formation property. It is conceivable that, in test pieces 1-1 and 1-2, the heating target was vacuum-suctioned onto the first surface of the base body by the flow path, and thereby the heating target was capable of contacting the first surface, over the entire surface. Since the high frequency electrode was arranged in a plane parallel to the first surface, the thickness of the base body located between the heating target and the high frequency electrode was uniformly ensured. Since a shower head was arranged parallel to the first surface, the distance between the heating target and the shower head was uniformly ensured. Accordingly, it is conceivable that, in test pieces 1-1 and 1-2, unevenness in film formation on the heating target by plasma treatment was suppressed.

Test piece 1-3, in which the third flow path was located closest to the first surface in the thickness direction in the base body, was significantly inferior in film formation property. It is conceivable that, in test piece 1-3, since the third flow path existed between the first surface and the high frequency electrode, and the base body located between the heating target and the high frequency electrode had an uneven thickness, unevenness in film formation occurred. Test piece 1-4, which did not include a flow path, was significantly inferior in film formation property. It is conceivable that, since test piece 1-4 did not include a flow path, warpage of the heating target was not corrected, and the heating target was not capable of contacting the first surface, over the entire surface.

### Second Test Example

In a second test example, a shield electrode was further provided in each of test pieces 1-1 and 1-2 in the first test example, and influences of the shield electrode on the film formation property for a heating target and the life of each heater were investigated.

### <<Test Pieces>>

The following test pieces 2-1, 2-2, 2-3, 2-4, and 2-5 were prepared. Test piece 2-1 was the same as test piece 1-1. Test piece 2-2 was the same as test piece 1-2. Test piece 2-3 was prepared by further arranging a shield electrode in test piece 2-1. Test piece 2-4 and test piece 2-5 were each prepared by further arranging a shield electrode in test piece 2-2. In test pieces 2-4 and 2-5, the positions of shield electrode 6 were different. In test pieces 2-3, 2-4, and 2-5, the material for the shield electrode, and the shape and the size of the shield electrode were identical. Test pieces 2-3, 2-4, and 2-5 had different orders of arranging the high frequency electrode, the heating element, the third flow path, and the shield electrode. The orders of arranging the high frequency electrode, the heating element, the third flow path, and the shield electrode in the respective test pieces were as described below.

In test piece 2-3, the high frequency electrode, the shield electrode, the third flow path, and the heating element were arranged in order, from the side of the first surface toward the side of the second surface of the base body. Test piece 2-3 was the same as heater 1 shown in FIG. 11.

In test piece 2-4, the high frequency electrode, the heating element, the shield electrode, and the third flow path were arranged in order, from the side of the first surface toward the side of the second surface of the base body. Test piece 2-4 was the same as heater 1 shown in FIG. 12.

In test piece 2-5, the high frequency electrode, the shield electrode, the heating element, and the third flow path were arranged in order, from the side of the first surface toward the side of the second surface of the base body. Test piece 2-5 was the same as heater 1 shown in FIG. 13.

In the arrangement orders shown in Table 2, the left side indicates the side of the first surface, and the right side indicates the side of the second surface.

In each test piece, a heating target was mounted on the first surface of the base body. In each test piece, a suction pipe was connected to an gas exhaust of a second flow path as a portion of the flow path, and the heating target was vacuum-suctioned onto the first surface of the base body via the flow path.

### <<Film Formation Property>>

A thin film was formed on the heating target by plasma treatment. A plurality of measurement points were set in the heating target, and the thickness of the thin film at each measurement point was evaluated. The plurality of measurement points were provided at the central point of the heating target and in the peripheral edge portion of the heating target at regular intervals in the circumferential direction. It was investigated whether or not the thin film formed by plasma treatment for a predetermined time had a predetermined thickness at each measurement point. Evaluations of film formation property shown in Table 2 are as follows. “A” indicates that the thin film with the predetermined thickness was obtained in the predetermined time, and the test piece was excellent in film formation property. “B” indicates that the thin film with the predetermined thickness was not able to be obtained in the predetermined time, and the test piece was inferior in film formation property.

### <<Life of Heater>>

Formation of the thin film on the heating target by plasma treatment was performed 10000 times, and it was confirmed whether or not a damage occurred in the base body. Evaluations of the life of the heater shown in Table 2 are as follows. “A” indicates that no damage was found in the base body. “B” indicates that a slight damage was found in the base body.

TABLE 2

| | | Film | |
|---|---|---|---|
| Test | | Formation | Life of |
| Piece | Arrangement Order | Property | Heater |
| 2-1 | high frequency electrode-third flow path-heating element | B | B |
| 2-2 | high frequency electrode-heating element-third flow path | B | B |
| 2-3 | high frequency electrode-shield electrode-third flow path- | A | A |
| | heating element | | |
| 2-4 | high frequency electrode-heating element-shield electrode- | A | A |
| | third flow path | | |
| 2-5 | high frequency electrode-shield electrode-heating element- | A | A |
| | third flow path | | |

### <<As to Film Formation Property>>

As shown in Table 2, test pieces 2-3, 2-4, and 2-5, which included the shield electrode between the high frequency electrode and the third flow path, were excellent in film formation property. It is conceivable that, in test pieces 2-3, 2-4, and 2-5, occurrence of discharge in a space constituting the third flow path was suppressed by the shield electrode. Accordingly, it is conceivable that film formation was performed excellently without causing energy loss. On the other hand, test pieces 2-1 and 2-2, which did not include a shield electrode, were inferior in film formation property. It is conceivable that, in test pieces 2-1 and 2-2, discharge occurred in the space constituting the third flow path, and energy loss had an adverse effect on film formation.

### <<As to Life of Heater>>

As shown in Table 2, in test pieces 2-3, 2-4, and 2-5, which included the shield electrode between the high frequency electrode and the third flow path, a damage was less likely to occur in the base body. It is conceivable that, in test pieces 2-3, 2-4, and 2-5, occurrence of discharge in the space constituting the third flow path was suppressed by the shield electrode. Accordingly, it is conceivable that there was no adverse effect that would cause a damage in the base body. On the other hand, in test pieces 2-1 and 2-2, which did not include a shield electrode, a damage occurred in the base body. It is conceivable that, in test pieces 2-1 and 2-2, discharge occurred in the space constituting the third flow path, and the discharge had an adverse effect that would cause a damage in the base body.

### REFERENCE SIGNS LIST

1: heater
2: base body, 21: first surface, 22: second surface
3: high frequency electrode
4: heating element
5: flow path
51: first flow path
510: gas intake, 511: first gas intake, 512: second gas intake, 513: third gas intake
52: second flow path, 520: gas exhaust
53: third flow path,
531: central portion, 532: branch path, 533: circular path, 534: connection path
6: shield electrode
7: support body, 71: first end portion, 72: second end portion
8: chamber, 80: through hole
81: shower head
9: suction pipe
10: heating target
D1, D2, D3: distance
D5: depth, W5: width

1. A heater comprising:
a base body having a disk shape;
a high frequency electrode arranged inside the base body;
a heating element arranged inside the base body; and
a support body having a cylindrical shape,
the base body including
a first surface on which a heating target is mounted,
a second surface opposite to the first surface, and
a flow path connected to the first surface and the second surface,
the support body including
a sidewall portion having a cylindrical shape, and
a first end portion having a flange-like shape and integrally formed with the sidewall portion,
the first end portion being fixed to the base body by being attached to the second surface
the flow path including
a first flow path having a gas intake provided so as to open in the first surface,
a second flow path having a gas exhaust provided in the second surface so as to open into an inner space surrounded by an inner circumferential surface of the sidewall portion, and
a third flow path connecting the first flow path and the second flow path, the inner space including a suction pipe connected to the gas exhaust,
each of the high frequency electrode, the heating element, and the third flow path being arranged within an interior of the base body not including the first surface and the second surface, and in a plane parallel to the first surface,
the heating element and the third flow path being arranged closer to the second surface than the high frequency electrode.

2. The heater according to claim 1, wherein the third flow path is arranged closer to the second surface than the heating element.

3. The heater according to claim 1, wherein a distance between the high frequency electrode and the third flow path in a thickness direction of the base body is more than or equal to 2 mm.

4. The heater according to claim 1, further comprising a shield electrode arranged inside the base body, wherein
the shield electrode is arranged in a plane that is parallel to the first surface and is located between the high frequency electrode and the third flow path.

5. The heater according to claim 1, wherein
the number of the first flow paths is plural, and
the gas intakes are arranged side by side in a circumferential direction of the base body, in the first surface.

6. The heater according to claim 1, wherein
the number of the first flow paths is plural,
the number of the second flow paths is one,
wherein the gas intake is among a plurality of gas intakes provided in the first surface, and
lengths from the plurality of first gas intakes, respectively, to the gas exhaust along the first flow paths, the second flow path, and the third flow path are identical.

7. The heater according to claim 1, wherein
the number of the first flow paths is plural,
the number of the second flow paths is one,
wherein the gas intake is among a plurality of gas intakes provided in the first surface, including a second gas intake and a third gas intake, and
a length from the second gas intake to the gas exhaust along the first flow path, the second flow path, and the third flow path is different from a length from the third gas intake to the gas exhaust along the first flow path, the second flow path, and the third flow path.

8. The heater according to claim 1, wherein
the number of the first flow paths is plural,
the third flow path includes a plurality of branch paths extending radially from a center side of the base body,
the second flow path or a plurality of the second flow paths are connected to the center side of the base body in the third flow path, and
at least one of a plurality of the first flow paths is connected to a tip portion of one of the branch paths.

9. The heater according to claim 2, wherein a distance between the high frequency electrode and the third flow path in a thickness direction of the base body is more than or equal to 2 mm.

10. The heater according to claim 9, further comprising a shield electrode arranged inside the base body, wherein
the shield electrode is arranged in a plane that is parallel to the first surface and is located between the high frequency electrode and the third flow path.

11. The heater according to claim 2, wherein
the number of the first flow paths is plural, and
the gas intake is among a plurality of gas intakes arranged side by side in a circumferential direction of the base body, in the first surface.

12. The heater according to claim 2, wherein
the number of the first flow paths is plural,
the number of the second flow paths is one,
wherein the gas intake is among a plurality of first gas intakes provided in the first surface, and
lengths from the plurality of first gas intakes, respectively, to the gas exhaust along the first flow paths, the second flow path, and the third flow path are identical.

13. The heater according to claim 2, wherein
the number of the first flow paths is plural,
the number of the second flow paths is one,
wherein the gas intake is among a plurality of gas intakes provided in the first surface, including a second gas intake and a third gas intake, and
a length from the second gas intake to the gas exhaust along the first flow path, the second flow path, and the third flow path is different from a length from the third gas intake to the gas exhaust along the first flow path, the second flow path, and the third flow path.

14. The heater according to claim 2, wherein
the number of the first flow paths is plural,
the third flow path includes a plurality of branch paths extending radially from a center side of the base body,
the second flow path or a plurality of the second flow paths are connected to the center side of the base body in the third flow path, and
at least one of a plurality of the first flow paths is connected to a tip portion of one of the branch paths.

15. The beater according to claim 1, wherein
the third flow path is arranged in a plane that is located between the high frequency electrode and the heating element.

16. The heater according to claim 15, wherein
a distance between the high frequency electrode and the third flow path in a thickness direction of the base body is more than or equal to 2 mm.

17. The heater according to claim 15, further comprising a shield electrode arranged inside the base body, wherein
the shield electrode is arranged in a plane that is parallel to the first surface and is located between the high frequency electrode and the third flow path.
